(19) United States
(12) Patent Application Publication
(10) Pub. No.: US 2016/0365397 A1
(43) Pub. Date: Dec. 15, 2016

(54) ORGANIC LIGHT EMITTING DISPLAY DEVICE

(71) Applicant: Samsung Display Co., Ltd., Yongin-Si (KR)

(72) Inventors: Jun-Seon SEO, Hwaseong-si (KR); Woo-Jin OH, Seoul (KR)

(21) Appl. No.: 15/096,597

(22) Filed: Apr. 12, 2016

(30) Foreign Application Priority Data
Jun. 15, 2015 (KR) 10-2015-0084165

(51) Int. Cl. H01L 27/32; H01L 51/52

(52) U.S. Cl. CPC H01L 27/3246; H01L 27/322; H01L 51/5284; H01L 51/5253; H01L 27/3218; H01L 27/3216

(57) ABSTRACT

An organic light emitting display includes a substrate, a first semiconductor element, a first electrode, a first pixel defining layer, a first organic light emitting layer, a second electrode and a first color filter. The first semiconductor element is disposed on the substrate. The first electrode is electrically connected to the first semiconductor element. The first pixel defining layer disposed on the first electrode, and a first pixel opening, which exposes a portion of the first electrode, is defined through the first pixel defining layer. The first organic light emitting layer is disposed on the exposed portion of the first electrode. The second electrode is disposed on the first organic light emitting layer and the first pixel defining layer. The first color filter is disposed over the first pixel opening. The first color filter has a structure extending from the first pixel opening in a plan view.

This application claims priority to Korean Patent Application No. 10-2015-0084165, filed on Jun. 15, 2015, and all the benefits accruing therefrom under 35 U.S.C. §119, the content of which in its entirety is herein incorporated by reference.

### BACKGROUND

1. Field

Exemplary embodiments relate to an organic light emitting display apparatus. More particularly, exemplary embodiments relate to an organic light emitting display apparatus of a pentile type.

2. Description of the Related Art

An organic light emitting display apparatus displays an image using light emitted from a plurality of pixels. Each of the pixels typically includes red, blue and green sub-pixels.

Organic light emitting layers of the sub-pixels may include light emitting materials to emit a red light, a blue light and a green light, respectively. Alternatively, after the organic light emitting layers are formed to include light emitting materials to emit a white light, a plurality of color filters corresponding to the sub-pixels may be disposed, respectively.

### SUMMARY

When a pixel structure of an organic light emitting display apparatus of a pentile type includes a plurality of color filters having a stripe shape, the color filters may be arranged very close to one another and the displayed colors may be mixed. In particular, light generated by each organic light emitting layer of the organic light emitting display apparatus may pass through an adjacent color filter such that the displayed colors may be mixed. In addition, when a viewing angle increases along a vertical direction or a horizontal direction, a desired color may not be displayed.

Some exemplary embodiments provide an organic light emitting display apparatus including a plurality of pixels and a plurality of color filters arranged in a pentile type with improved display quality.

According to exemplary embodiments, an organic light emitting display includes a substrate, a first semiconductor element, a first electrode, a first pixel defining layer, a first organic light emitting layer, a second electrode and a first color filter. In such an embodiment, the first semiconductor element is disposed on the substrate. In such an embodiment, the first electrode is electrically connected to the first semiconductor element. In such an embodiment, the first pixel defining layer is disposed on the first electrode, and a first pixel opening, which exposes a portion of the first electrode, is defined through the first pixel defining layer. In such an embodiment, the first organic light emitting layer is disposed on the exposed portion of the first electrode through the first pixel opening. In such an embodiment, the second electrode is disposed on the first organic light emitting layer and the first pixel defining layer. In such an embodiment, the first color filter is disposed over the first pixel opening. In such an embodiment, the first color filter has a structure extending from the first pixel opening in a plan view.

In exemplary embodiments, the first color filter may extend from the first pixel opening by a constant distance in a plan view.

In exemplary embodiments, the organic light emitting display apparatus may further include a second semiconductor element, a third electrode, a second pixel defining layer, a second organic light emitting layer, a fourth electrode and a second color filter. In such an embodiment, the second semiconductor element may be disposed on the substrate. In such an embodiment, the third electrode may be electrically connected to the second semiconductor element. In such an embodiment, the second pixel defining layer disposed on the second electrode, and a second pixel opening, which expose a portion of the third electrode, is defined through the second pixel defining layer. In such an embodiment, the second organic light emitting layer may be disposed on the exposed portion of the third electrode through the second pixel opening. In such an embodiment, the fourth electrode may be disposed on the second organic light emitting layer and the second pixel defining layer. In such an embodiment, the second color filter may be disposed over the second pixel opening. In such an embodiment, the second color filter may have a structure extending from the second pixel opening in a plan view. In such an embodiment, an area of the first color filter may be greater than an area of the second color filter in a plan view.

In exemplary embodiments, the first organic light emitting layer may emit a red light or a blue light, and the second organic light emitting layer may emit a green light.

In exemplary embodiments, the first and second organic light emitting layers may emit a white light.

In exemplary embodiments, the first color filter may be a red color filter or a blue color filter, and the second color filter may be a green color filter.

In exemplary embodiments, the organic light emitting display apparatus may further include a black matrix disposed at a boundary between the first and second color filters.

In exemplary embodiments, the organic light emitting display apparatus may further includes an overcoating layer interposed between the first and second color filters and between the second and fourth electrodes.

In exemplary embodiments, the organic light emitting display apparatus may further includes a plurality of first pixels disposed on the substrate, and a plurality of second pixels disposed on the substrate. In such an embodiment, each of the first pixels is defined by the first pixel defining layer, and each of the second pixels is defined by the second pixel defining layer.

In exemplary embodiments, the first pixels may be arranged along a first direction and a second direction crossing the first direction. In such an embodiment, each of the second pixels may be positioned in a direction, which forms an acute angle with the first and second directions, from an adjacent first pixel thereof among the first pixels.

In exemplary embodiments, the first pixels may correspond to a first color or a second color, and the second pixels may correspond to a third color.

In exemplary embodiments, the first color may be a red color, and the second color may be a blue color, and the third color may be a green color. In such an embodiment, the first color filter may be a red color filter or a blue color filter. In such an embodiment, the second color filter may be a green color filter.

In exemplary embodiments, the blue color filters may extend in a plan view to contact the red color filter and the green color filter.

In exemplary embodiments, the red color filters may extend in a plan view to contact the blue color filter and the green color filter.

In exemplary embodiments, the organic light emitting display apparatus may have a pixel arrangement structure of a pentile type.

According to exemplary embodiments, an organic light emitting display includes a substrate, a first semiconductor element, a first electrode, a first pixel defining layer, a first organic light emitting layer, a second electrode and a first color filter. In such an embodiment, the first semiconductor element is disposed on the substrate. In such an embodiment, the first electrode is electrically connected to the first semiconductor element. In such an embodiment, the first pixel defining layer disposed on the first electrode, and a first pixel opening, which exposes a portion of the first electrode, is defined through the first pixel defining layer. In such an embodiment, the first organic light emitting layer is disposed on the exposed portion of the first electrode through the first pixel opening. In such an embodiment, the second electrode is disposed on the first organic light emitting layer and the first pixel defining layer. In such an embodiment, the first color filter is disposed over the first pixel opening. In such an embodiment, the first color filter has a structure extending from the first pixel opening in a plan view. In such an embodiment, the first color filter has a rhombus shape in a plan view.

In exemplary embodiments, the organic light emitting display apparatus may further include a second semiconductor element, a third electrode, a second pixel defining layer, a second organic light emitting layer, a fourth electrode and a second color filter. In such an embodiment, the second semiconductor element may be disposed on the substrate. In such an embodiment, the third electrode may be electrically connected to the second semiconductor element. In such an embodiment, the second pixel defining layer is disposed on the third electrode and a second pixel opening, which exposes a portion of the third electrode, is defined through the second pixel defining layer. In such an embodiment, the second organic light emitting layer is disposed on the exposed portion of the third electrode. In such an embodiment, the fourth electrode is disposed on the second organic light emitting layer and the second pixel defining layer. In such an embodiment, the second color filter is disposed over the second pixel opening. In such an embodiment, the second color filter has a structure extending from the second pixel opening in a plan view. In such an embodiment, the second color filter has a rhombus shape in a plan view. In such an embodiment, an area of the first pixel opening is greater than an area of the second pixel opening in a plan view.

In exemplary embodiments, the first and second color filters may contact each other in a plan view.

In exemplary embodiment, a side of the rhombus shape of the first color filter and a side of the rhombus shape of the second color filter may contact each other in a plan view.

In exemplary embodiments, the first color filter may be a red color filter or a blue color filter, and the second color filter may be a green color filter.

According to exemplary embodiments of the inventive concept, the color filters may extend from the openings of the sub-pixels such that shapes of the color filters are substantially the same as the shapes of the openings of the sub-pixels. In such an embodiment, the color filters are spaced apart from one another with a predetermined distance, the displayed colors are effectively prevented from being mixed.

In such embodiments, when the color filters have a rhombus shape, it may be prevented that a residual layer is sandwiched between the color filters adjacent to each other. Accordingly, when a margin of the blue color filter is maximized, reddish or greenish problem of an image may be reduced.

### BRIEF DESCRIPTION OF THE DRAWINGS

Illustrative, non-limiting exemplary embodiments will be more clearly understood from the following detailed description taken in conjunction with the accompanying drawings.

FIG. 1 is a plan view illustrating an exemplary embodiment of an organic light emitting display apparatus, according to the inventive concept.

FIG. 2 is a cross-sectional view cut along line I-I′ of FIG. 1.

FIG. 3 is a plan view illustrating an alternative exemplary embodiment of an organic light emitting display apparatus, according to the inventive concept.

FIG. 4 is a cross-sectional view cut along line II-II′ of FIG. 3.

FIGS. 5A and 5B are plan views illustrating other alternative exemplary embodiments of an organic light emitting display apparatus according to the inventive concept.

FIGS. 6A to 6D are cross-sectional views illustrating an exemplary embodiment of a method of manufacturing an organic light emitting display apparatus, according to the inventive concept.

### DETAILED DESCRIPTION

Various exemplary embodiments will be described more fully with reference to the accompanying drawings, in which embodiments are shown. This inventive concept may, however, be embodied in many different forms and should not be construed as limited to the embodiments set forth herein. Rather, these embodiments are provided so that this disclosure will be thorough and complete, and will fully convey the scope of the inventive concept to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the inventive concept. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, exemplary embodiments of the invention will be described in detail with reference to the accompanying drawings.

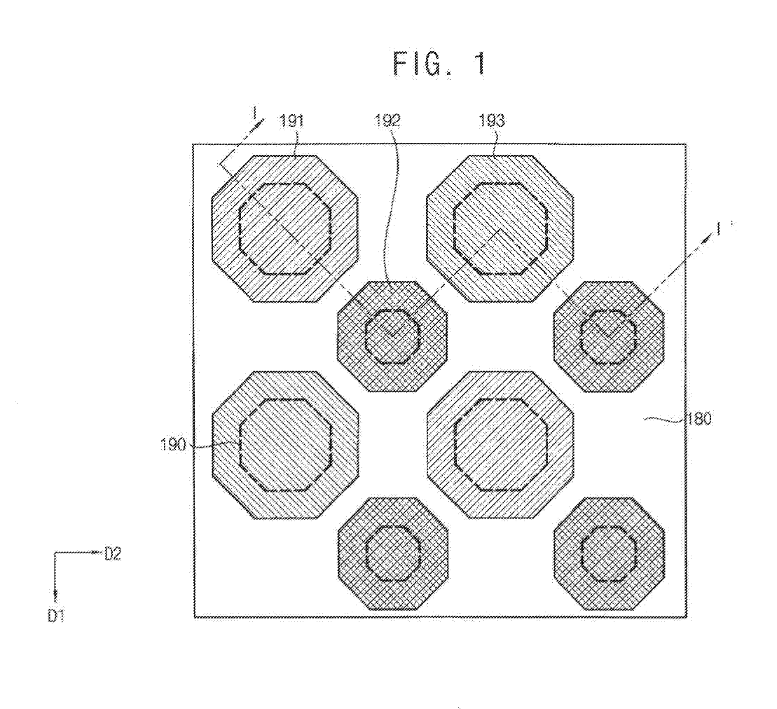

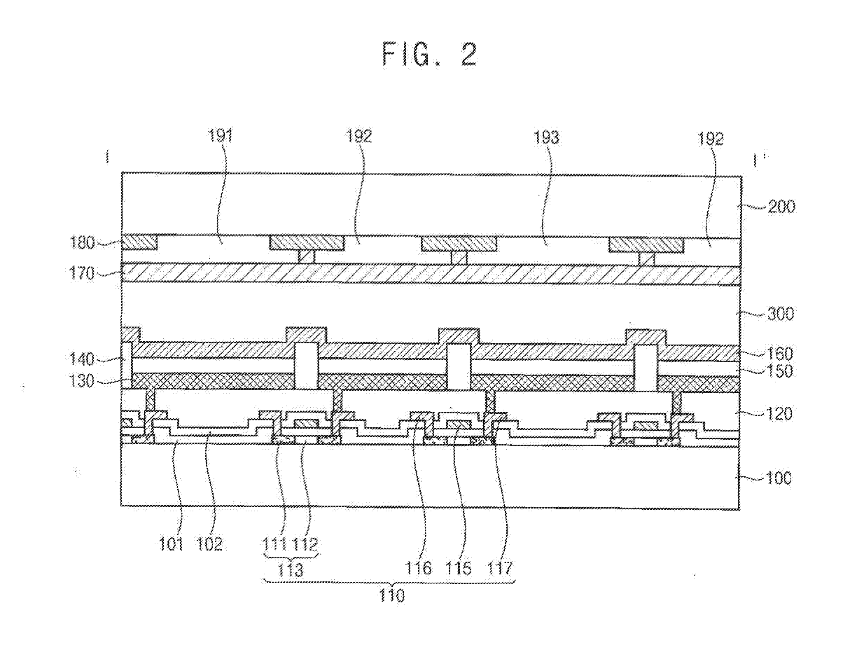

FIG. 1 is a plan view illustrating an exemplary embodiment of an organic light emitting display apparatus according to the inventive concept. FIG. 2 is a cross-sectional view cut along line I-I′ of FIG. 1.

Referring to FIGS. 1 and 2, an exemplary embodiment of an organic light emitting display apparatus includes a first substrate 100, a second substrate 200, an adhesive layer 300, a semiconductor element 110, a first insulation layer 101, a second insulation layer 102, a via insulation layer 120, a first electrode 130, a pixel defining layer 140, an organic light emitting layer 150, a second electrode 160, a black matrix 180, a color filter and an overcoating layer 170.

A plurality of sub-pixel areas may be defined on the first substrate 100 substantially in a matrix form, e.g., a matrix including m columns and n rows. The color filter may include a plurality of color filters 191, 192 and 193. The color filters 191, 192 and 193 may be disposed or arranged under the second substrate 200, which is opposite to the first substrate 100.

The first and second substrates 100 and 200 may be arranged to face each other. The first and second substrates 100 and 200 may be combined with each other by the adhesive layer 300. Each of the first and second substrates 100 and 200 may include a transparent insulation substrate, for example.

In one exemplary embodiment, for example, the first and second substrates 100 and 200 may include a glass substrate, a quartz substrate or a transparent resin substrate, etc. In one exemplary embodiment, for example, the transparent resin substrate for the first and second substrates 100 and 200 may include polyimide-based resin, acryl-based resin, polyacrylate-based resin, polycarbonate-based resin, polyether-based resin, sulfonic acid containing resin, or polyethyleneterephthalate-based resin, etc.

The adhesive layer 300 may have a thickness in a range of about 5 micrometers (μm) to about 8 μm for an effective adhesion maintaining between the first and second substrates 100 and 200.

The adhesive layer 300 may include a resin having transparent and adhesive characteristic. In one exemplary embodiment, for example, the adhesive layer 300 may include an epoxy resin.

The semiconductor element 110 may be disposed on the first substrate 110. The semiconductor element 110 may include an active layer 113, a gate electrode 115, a source electrode 116 and a drain electrode 117, etc. The active layer 113 may include an impurity region 111 and a channel region 112. The active layer 113 may include silicon.

The active layer 113 may include a semiconductor oxide including a binary compound (ABx), a ternary compound (ABxCy) and/or a quaternary compound (ABxCyDz). In one exemplary embodiment, for example, the active layer 113 may include indium (In), zinc (Zn), gallium (Ga), stannum (Sn), titanium (Ti), aluminum (Al), hafnium (Hf), zirconium (Zr) and/or magnesium (Mg).

The gate electrode 115 may include metal, alloy, conductive metal oxide or a transparent conductive material, etc. In one exemplary embodiment, for example, the gate electrode 115 may include, or be formed using, aluminum (Al), alloy including aluminum, aluminum nitride (AlNx), silver (Ag), alloy including silver, tungsten (W), tungsten nitride (WNx), copper (Cu), alloy including copper, nickel (Ni), alloy containing nickel, chrome (Cr), chrome nitride (CrNx), molybdenum (Mo), alloy containing molybdenum, titanium (Ti), titanium nitride (TiNx), platinum (Pt), tantalum (Ta), tantalum nitride (TaNx), neodymium (Nd), scandium (Sc), strontium ruthenium oxide (SRO), zinc oxide (ZnOx), indium tin oxide (“ITO”), tin oxide (SnOx), indium oxide (InOx), gallium oxide (GaOx) indium zinc oxide (“IZO”), or a combination thereof. In exemplary embodiments, the gate electrode 115 may have a single layer structure or a multi-layer structure, which may include a metal film, an alloy film, a metal nitride film, a conductive metal oxide film and/or a transparent conductive film.

A pattern (not shown) electrically connected to the gate electrode 115 may include a signal line to transmit driving signal for the sub-pixels. The source electrode 116 and the drain electrode 117 may be electrically connected to the active layer 113 via a hole defined through the first and second insulation layers 101 and 102.

In exemplary embodiments, the semiconductor element 110 may be a thin film transistor. In addition to the thin film transistor to drive the sub-pixels illustrated in FIG. 2, another element may further be disposed in an exemplary embodiment of the organic light emitting display apparatus. In one exemplary embodiment, for example, a switching transistor, a storage capacitor, etc., may be disposed on the first substrate 100. In an exemplary embodiment as shown in FIG. 2, a transistor may be a top gate type, but not being limited thereto. Alternatively, the transistor may be a bottom gate type.

The first insulation layer 101 may be disposed on the first substrate 100 to cover the active layer 110. The first insulation layer 101 may be provided or formed by a chemical vapor deposition (“CVD”) process, a spin coating process, a plasma enhanced chemical vapor deposition (“PECVD”) process, a sputtering process, a vacuum evaporation process, a high density plasma-chemical vapor deposition (“HDP-CVD”) process or a printing process, for example.

The first insulation layer 101 may include a silicon compound or metal oxide, for example. In one exemplary embodiment, for example, the first insulation layer 101 may include, or be formed using, silicon oxide (SiOx), silicon nitride (SiNx), silicon oxynitride (SiOxNy), aluminum oxide (AlOx), tantalum oxide (TaOx), hafnium oxide (HfOx), zirconium oxide (ZrOx), titanium oxide (TiOx), or a combination thereof.

The second insulation layer 102 may be disposed on the first insulation layer 101 to cover the gate electrode 115. The second insulation layer 102 may be provided or formed by a CVD process, a spin coating process, a PECVD process, a sputtering process, a vacuum evaporation process, a HDP-CVD process or a printing process, for example.

In an exemplary embodiment, the second insulation layer 102 may have a single-layered structure or a multi-layer structure including at least two insulation films. The second insulation layer 102 may include, or be formed using, an organic material. In one exemplary embodiment, for example, the second insulation layer 102 may include photoresist, acryl-based resin, polyimide-based resin, polyamide-based resin, siloxane-based resin, or a combination thereof. Alternatively, the second insulation layer 102 may include an inorganic material. In one exemplary embodiment, for example, the second insulation layer 102 may include or, be formed using, silicon oxide, silicon nitride, silicon oxynitride, silicon oxycarbide, aluminum, magnesium, zinc, hafnium, zirconium, titanium, tantalum, aluminum oxide, titanium oxide, tantalum oxide, magnesium oxide, zinc oxide, hafnium oxide, zirconium oxide, titanium oxide, or a combination thereof.

The via insulation layer 102 may be disposed to substantially cover the second insulation layer 102, the source electrode 116 and the drain electrode 117. The first insulation layer 130 may have a substantially planarized surface, as illustrated in FIG. 2.

The via insulation layer 102 may be provided or formed by a spin coating process or a slit coating process using polyimide, epoxy-based resin, acryl-based resin, polyester, etc.

In an exemplary embodiment, a via hole may be formed in the via insulation layer 102 by partially etching the via insulation layer 102. A top surface of the drain electrode 117 may be exposed through the via hole.

The first electrode 130 may extend through the via hole in the via insulation layer 120 to be electrically connected to the drain electrode 117. In exemplary embodiments, the first electrode 130 may have a single layer structure or a multi-layer structure, which may include a metal film, an alloy film, a metal nitride film, a conductive metal oxide film and/or a transparent conductive film.

The pixel defining layer 140 may be disposed on the via insulation layer 120 on which the first electrode 130 is arranged. The pixel defining layer 140 may include an organic material, or an inorganic material.

In one exemplary embodiment, for example, the pixel defining layer 140 may include or, be formed using, photoresist, acryl-based resin, polyacryl-based resin, polyimide-based resin or a silicon compound, for example. A sub-pixel opening 190 is defined in the pixel defining layer 140 in each of the sub-pixel areas.

The organic light emitting layer 150 may be disposed on a portion of the first electrode 130 exposed by the sub-pixel opening 190 of the pixel defining layer 140. The organic light emitting layer 150 may extend on a sidewall of the sub-pixel opening 190 of the pixel defining layer 140.

The organic light emitting layer 150 may be provided or formed by a laser induced thermal imaging process, or a printing process, for example. The organic light emitting layer 150 may include an organic light emitting layer (“EL”), a hole injection layer (“HIL”), a hole transfer layer (“HTL”), an electron transfer layer (“ETL”), an electron injection layer (“EIL”), etc.

In exemplary embodiments, the organic light emitting layer 150 may include light emitting materials for generating different colors of light such as a red color of light (R), a green color of light (G) and a blue color of light (B), which may be determined based on the positions of the sub-pixel areas. Alternatively, the organic light emitting layer 150 may include an emitting material for generating white color of light.

The second electrode 160 may be disposed on the pixel defining layer 140, the organic light emitting layer 150 and the via insulation layer 120. The second electrode 160 may include magnesium (Mg) or silver (Ag).

The black matrix 180, and the color filters 191, 192 and 193 may be disposed on an inner surface of the second substrate 200 or under a bottom of the second substrate 200. The black matrix 180 may be disposed to overlap a transistor region including the active layer 110 and a line region including a gate line and a data line to block light leakage in an region where a unstable electric field may be generated.

In exemplary embodiments, the black matrix 180 may be disposed or arranged at a boundary between the color filters 191, 192 and 193. The black matrix 180 may effectively prevent the light generated by the organic light emitting layer 150 from passing through the color filters of the adjacent sub-pixels such that color mixing is reduced.

In exemplary embodiments, the overcoating layer 170 may be disposed on the color filters 191, 192 and 193 and the black matrix 180. The overcoating layer 170 may include an organic insulation material such as benzocyclobutene or photoacryl, for example. The overcoating layer 170 may serve or function as a protection layer, which covers and protects a layer therebelow.

The color filters 191, 192 and 193 may correspond to the sub-pixels, respectively, under a bottom of the second substrate 200. The color filters may have a structure extending from the sub-pixel opening 190 in a plan view. In exemplary embodiment, the color filters 191, 192 and 193 may extend from the sub-pixel opening 190 by a constant distance in all directions in a plan view. In such an embodiment, the color filters 191, 192 and 193 may cover the sub-pixel opening 190, and the sub-pixel opening 190 may be disposed in a middle portion of the color filters 191, 192 and 193. The extension distance may be determined based on a process margin of the color filters 191, 192 and 193. The color filters 191, 192 and 193 may be spaced apart from one another such that the color mixing due to the light generated by the organic light emitting layer 150 from passing through the color filters of the adjacent sub-pixels is reduced.

In exemplary embodiments, the color filters 191, 192 and 193 may be red, green and blue color filters, respectively. An area of the red color filter 191 may be greater than an area of the green color filter 192 in a plan view. An area of the blue color filter 193 may be greater than the area of the green color filter 192 in a plan view. The areas of the red and blue color filters 191 and 193 may be substantially the same as each other.

The red and blue color filters 191 and 193 may be arranged along a first direction D1 and a second direction D2 crossing the first direction D1. The green color filter 192 may be positioned in a direction, which forms an acute angle with the first and second directions D1 and D2, from the entire red and blue color filters 191 and 193.

In exemplary embodiments, the organic light emitting display apparatus may have a pixel arrangement structure of a pentile type.

According to exemplary embodiments, the color filters 191, 192 and 193 may extend from the sub-pixel openings of the sub-pixels such that shapes of the color filters 191, 192 and 193 are substantially the same as the shapes of the sub-pixel openings 190 of the sub-pixels. In such an embodiment, the color filters 191, 192 and 193 are spaced apart from one another by a predetermined distance, such that the displayed colors of adjacent sub-pixels are effectively prevented from being mixed.

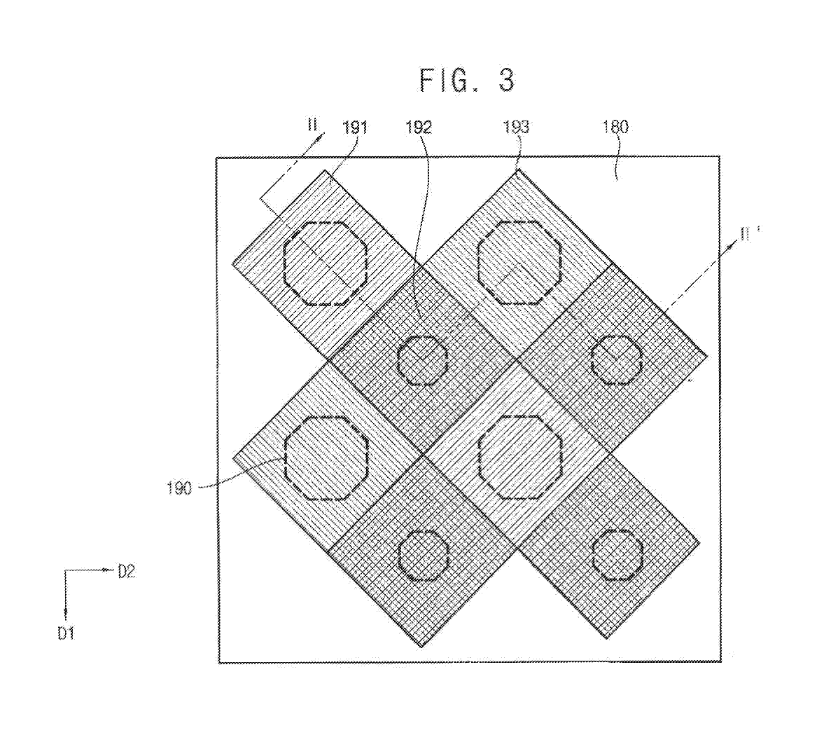

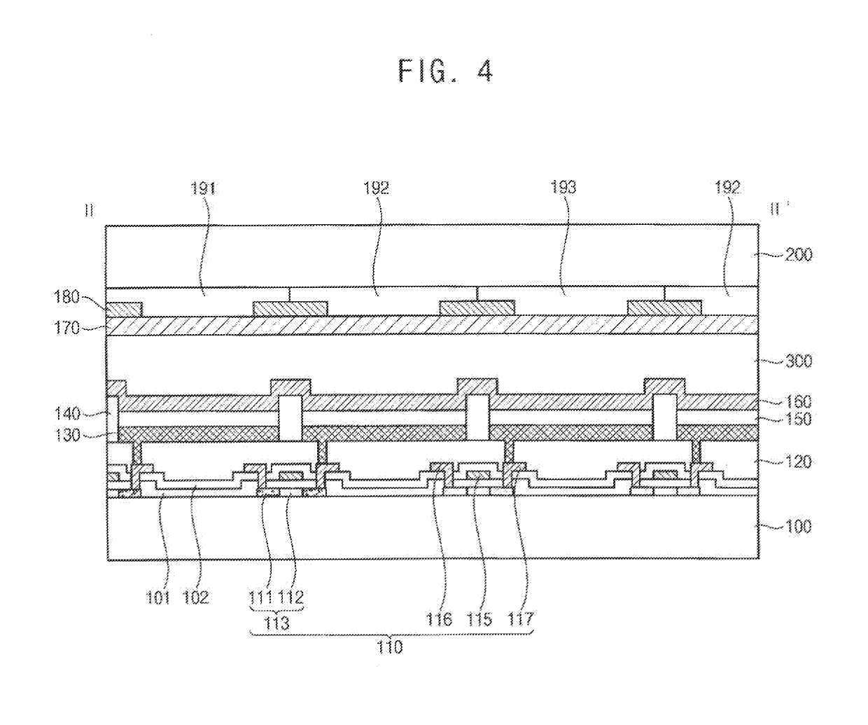

FIG. 3 is a plan view illustrating an alternative exemplary embodiment of an organic light emitting display apparatus, according to the inventive concept. FIG. 4 is a cross-sectional view cut along line II-II′ of FIG. 3. The organic light emitting display apparatus shown in FIGS. 3 and 4 may be substantially the same as that shown in FIGS. 1 and 2 except for the shape of the color filters. The same or like elements shown in FIGS. 3 and 4 have been labeled with the same reference characters as used above to describe the exemplary embodiments of the organic light emitting display apparatus with reference to FIGS. 1 and 2, and any repetitive detailed description thereof will hereinafter be omitted or simplified.

Referring to FIGS. 3 and 4, an exemplary embodiment of an organic light emitting display apparatus includes a first substrate 100, a second substrate 200, an adhesive layer 300, a semiconductor element 110, a first insulation layer 101, a second insulation layer 102, a via insulation layer 120, a first electrode 130, a pixel defining layer 140, an organic light emitting layer 150, a second electrode 160, a black matrix 180, a color filter and an overcoating layer 170.

The color filter includes a plurality of color filters 191, 192 and 193. The black matrix 180 and color filters 191, 192 and 193 may be disposed on an inner surface of the second substrate 200 or under a bottom of the second substrate 200. In an exemplary embodiment, the color filters 191, 192 and 193 may expose a portion of the black matrix 180 as shown in FIG. 1. In an alternative exemplary embodiment, the color filters 191, 192 and 193 may cover the black matrix 180 as shown in FIG. 4. In such an embodiment, where the color filters 191, 192 and 193 cover the black matrix 180, the color filters 191, 192 and 193 may have substantially the same width as each other.

In exemplary embodiments, the color filters 191, 192 and 193 may be red, green and blue color filters, respectively. The color filters may have a structure extending from a sub-pixel opening 190 in a plan view. The color filters may have a rhombus shape in a plan view.

An area of a sub-pixel opening 190 under the red or blue color filters 191 or 193 may be greater than an area of a sub-pixel opening 190 under the green color filter 192.

In exemplary embodiments, the red and green color filters 191 and 192 may contact each other in a plan view. In such an embodiment, the blue and green color filters 193 and 192 may contact each other in a plan view.

In exemplary embodiments, as shown in FIG. 3, a side of the rhombus shape of the red color filter 191 and a side of the rhombus shape of the green color filter 192 may contact each other in a plan view.

In exemplary embodiments, as shown in FIG. 3, a side of the rhombus shape of the blue color filter 193 and the side of the rhombus shape of the green color filter 192 may contact each other in a plan view.

According to exemplary embodiments, the color filters 191, 192 and 193 may extend from the sub-pixel openings 190 of the sub-pixels. When the color filters 191, 192 and 193 have a rhombus shape, a residual layer, which is disposed between the color filters adjacent to each other, may be omitted.

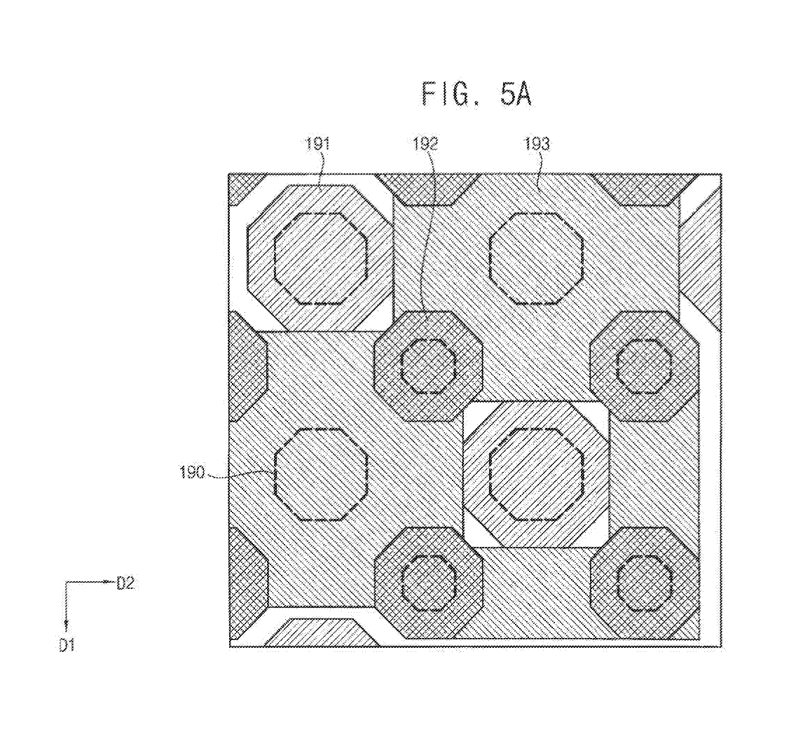

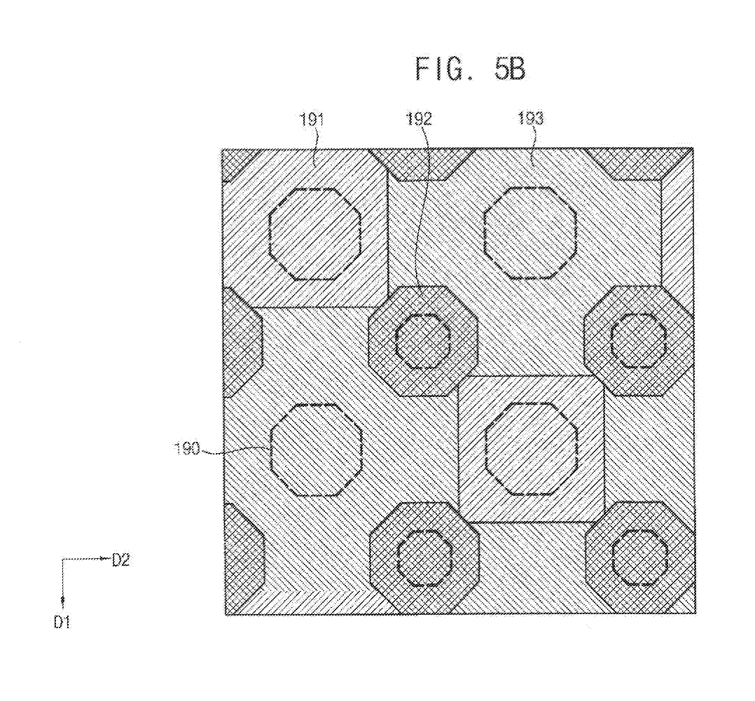

FIGS. 5A and 5B are plan views illustrating other alternative exemplary embodiments of an organic light emitting display apparatus, according to the inventive concept. The organic light emitting display apparatus shown in FIGS. 5A or 5B may be substantially the same as that illustrated in FIGS. 1 and 2 except for the shape of the color filters. The same or like elements shown in FIGS. 5A and 5B have been labeled with the same reference characters as used above to describe the exemplary embodiments of the organic light emitting display apparatus with reference to FIGS. 1 and 2, and any repetitive detailed description thereof will hereinafter be omitted or simplified.

Referring to FIGS. 5A and 5B, in an exemplary embodiment, a plurality of color filters 191, 192 and 193 may be red, green and blue color filters, respectively. The color filters may have a structure extending from a sub-pixel opening 190 in a plan view.

An area of a sub-pixel opening 190 under the red or blue color filters 191 or 193 may be greater than an area of a sub-pixel opening 190 under the green color filter 192.

As illustrated in FIG. 5A, in exemplary embodiments, the blue color filter 193 may contact the red and green color filters 191 and 192, and the red and green color filters 191 and 192 may be spaced apart from each other.

As illustrated in FIG. 5B, in exemplary embodiments, the blue color filter 193 may contact the red and green color filters 191 and 192. The red color filter 191 may contact the blue and green color filters 193 and 192.

According to exemplary embodiments, the color filters 191, 192 and 193 may extend from the sub-pixel openings 190 of the sub-pixels. When a margin of the blue or red color filter 193 or 191 is maximized, that is, when the blue or red color filter 193 or 191 is expanded to contact the green color filter 192, reddish or greenish problem of an image may be reduced.

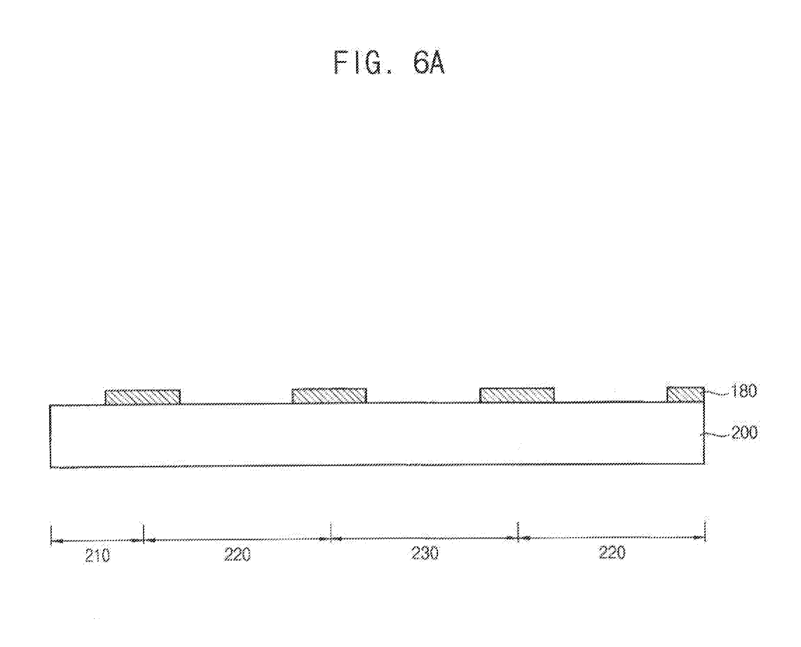

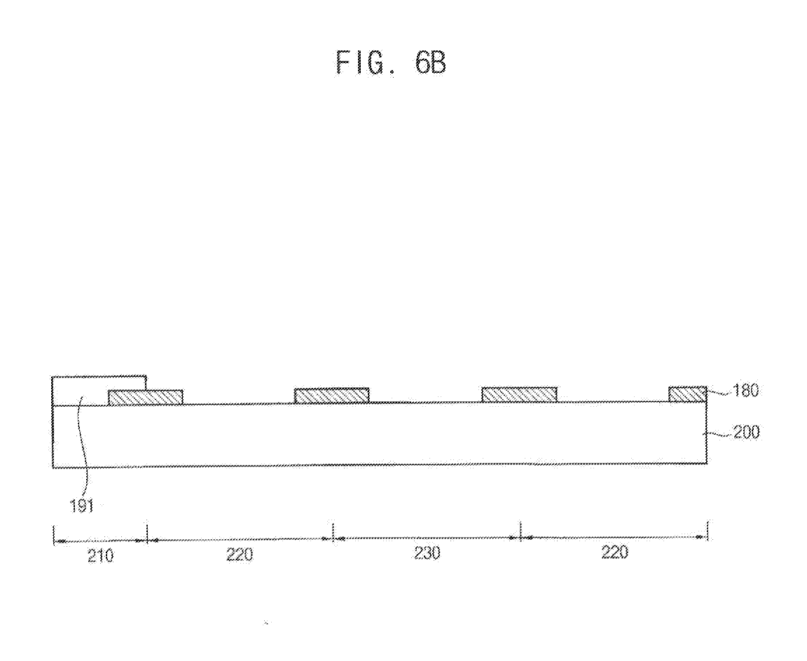

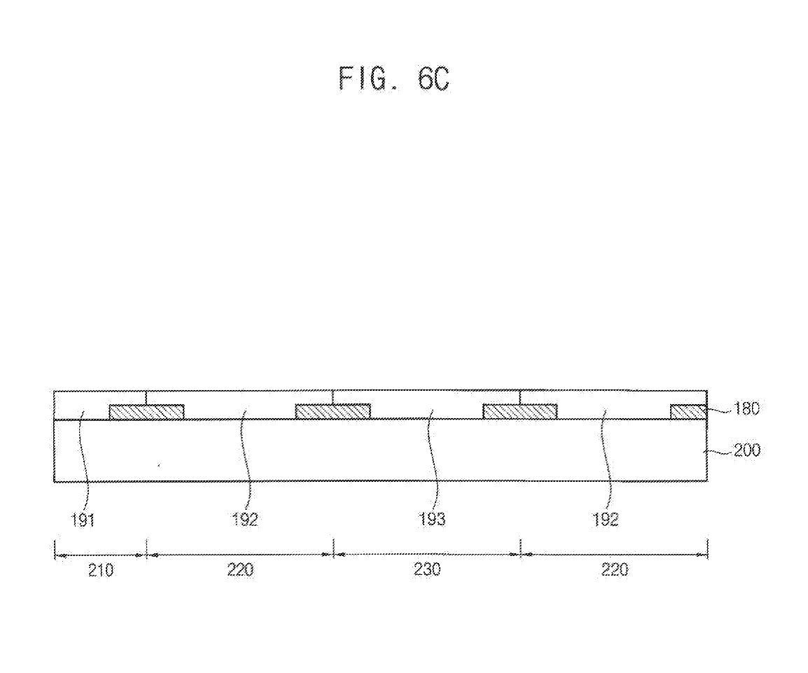

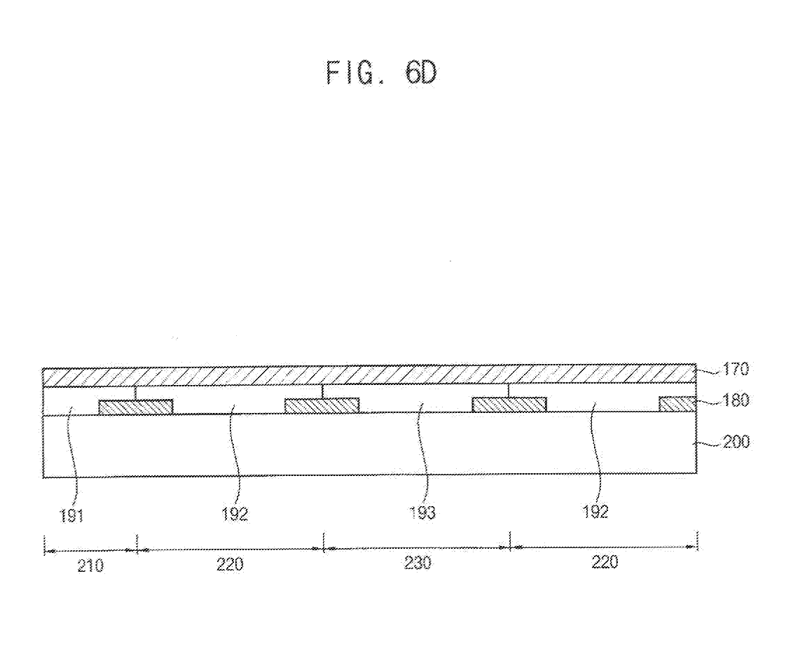

FIGS. 6A to 6D are cross-sectional views illustrating an exemplary embodiment of a method of manufacturing an organic light emitting display apparatus, according to the inventive concept.

A method of forming a lower panel including the first substrate of an organic light emitting display apparatus according to exemplary embodiments is substantially the same as a general method of forming a lower panel of an organic light emitting display apparatus. Detailed descriptions thereon are omitted herein.

Referring to FIG. 6A, a black resin may be provided or stacked on a transparent second substrate 200, and a mask process may be performed such that a black matrix 180 is formed on a boundary between a plurality of color filter regions 210, 220 and 230. The second substrate 200 may include glass or plastic.

Referring to FIG. 6B, a first resist may be stacked on the second substrate 200 to form a red color filter 191, and a mask process including exposure and development using a exposure mask such that the red color filter 191 is formed on a first color filter area 210.

Alternatively, the red color filter 191 may be formed by performing a thermal transfer process.

Referring to FIG. 6C, by performing substantially the same process as manufacturing the red color filter 191, green and blue color filters 192 and 193 may be formed on second and third color filter regions 220 and 230. The red, green, blue and green color filters 191, 192 and 193 may be formed on the second substrate 200, sequentially and repeatedly.

Two color filters having different colors from each other may be formed in the boundary between the color filters 191, 192 and 193. In an exemplary embodiment, the two color filters may overlap each other. Alternatively, the two color filters may not overlap each other and the two color filters may be form to be close to each other.

Referring to FIG. 6D, a transparent organic insulation material may be provided or stacked on the color filters 191, 192 and 193 to form an overcoating layer 170. The overcoating layer 170 may include the organic insulation material such as benzocyclobutene or photoacryl, for example.

The overcoating layer 170 may be formed by performing a spin coating process or a roll coating process with the organic insulation material having photosensitivity. By forming the overcoating layer 170, an upper panel of an organic light emitting display apparatus according to exemplary embodiments may be prepared as shown in FIG. 6D.

Referring back to FIG. 4, a switching transistor (not shown), a driving transistor 110, a pixel defining layer 140 and an organic light emitting layer 150 may be provided or formed on the first substrate 100.

After the first and second substrates 100 and 200 are aligned to face each other, a resin having a transparent and adhesive characteristic may be interposed between the first and second substrates 100 and 200. The resin may include an epoxy-based resin.

The first and second substrates 100 and 200 may be combined to align the organic light emitting layer 150 and the color filters 191, 192 and 193 formed thereon, respectively, to manufacture the organic light emitting display apparatus.

The foregoing is illustrative of exemplary embodiments and is not to be construed as limiting thereof. Although a few exemplary embodiments have been described, those skilled in the art will readily appreciate that many modifications are possible in exemplary embodiments without materially departing from the novel teachings and advantages of the present inventive concept. Accordingly, all such modifications are intended to be included within the scope of exemplary embodiments as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. An organic light emitting display apparatus comprising:
a substrate;
a first semiconductor element disposed on the substrate;
a first electrode electrically connected to the first semiconductor element;
a first pixel defining layer disposed on the first electrode, wherein a first pixel opening, which exposes a portion of the first electrode, is defined through the first pixel defining layer;
a first organic light emitting layer disposed on the exposed portion of the first electrode through the first pixel opening;
a second electrode disposed on the first organic light emitting layer and the first pixel defining layer; and
a first color filter disposed over the first pixel opening,
wherein the first color filter has a structure extending from the first pixel opening in a plan view.

2. The organic light emitting display apparatus of claim 1, wherein the first color filter extends from the first pixel opening by a constant distance in a plan view.

3. The organic light emitting display apparatus of claim 1, further comprising:
a second semiconductor element disposed on the first substrate;
a third electrode electrically connected to the second semiconductor element;
a second pixel defining layer disposed on the third electrode, wherein a second pixel opening, which exposes a portion of the third electrode, is defined through the second pixel defining layer;
a second organic light emitting layer disposed on the exposed portion of the third electrode through the second pixel defining layer;
a fourth electrode disposed on the second organic light emitting layer and the second pixel defining layer; and
a second color filter disposed over the second pixel opening,
wherein the second color filter has a structure extending from the second pixel opening in a plan view, and
wherein an area of the first color filter is greater than an area of the second color filter in a plan view.

4. The organic light emitting display apparatus of claim 3, wherein
the first organic light emitting layer emits a red light or a blue light, and
the second organic light emitting layer emits a green light.

5. The organic light emitting display apparatus of claim 3, wherein the first and second organic light emitting layers emits a white light.

6. The organic light emitting display apparatus of claim 5, wherein
the first color filter is a red color filter or a blue color filter, and
the second color filter is a green color filter.

7. The organic light emitting display apparatus of claim 3, further comprising:
a black matrix disposed at a boundary between the first and second color filters.

8. The organic light emitting display apparatus of claim 3, further comprising:
an overcoating layer interposed between the first and second color filters, and between the second and fourth electrodes.

9. The organic light emitting display apparatus of claim 3, further comprising:
a plurality of first pixels disposed on the substrate; and
a plurality of second pixels disposed on the substrate,
wherein each of the first pixels is defined by the first pixel defining layer, and
wherein each of the second pixels is defined by the second pixel defining layer.

10. The organic light emitting display apparatus of claim 9, wherein
the first pixels are arranged along a first direction and a second direction crossing the first direction, and
each of the second pixels is positioned in a direction, which forms an acute angle with the first and second directions, from an adjacent first pixel thereof among the first pixels.

11. The organic light emitting display apparatus of claim 10, wherein
the first pixels correspond to a first color or a second color, and
the second pixels correspond to a third color.

12. The organic light emitting display apparatus of claim 11, wherein
the first color is a red color,
the second color is a blue color,
the third color is a green color,
the first color filter is a red color filter or a blue color filter, and
the second color filter is a green color filter.

13. The organic light emitting display apparatus of claim 12, wherein the blue color filter extends in a plan view to contact the red color filter and the green color filter.

14. The organic light emitting display apparatus of claim 12, wherein the red color filter extends in a plan view to contact the blue color filter and the green color filter.

15. The organic light emitting display apparatus of claim 9, wherein the organic light emitting display apparatus has a pixel arrangement structure of a pentile type.

16. An organic light emitting display apparatus comprising:
a substrate;
a first semiconductor element disposed on the substrate;
a first electrode electrically connected to the first semiconductor element;
a first pixel defining layer disposed on the first electrode, wherein a first pixel opening, which exposes a portion of the first electrode, is defined in the first pixel defining layer;
a first organic light emitting layer disposed on the exposed portion of the first electrode through the first pixel opening;
a second electrode disposed on the first organic light emitting layer and the first pixel defining layer; and
a first color filter disposed over the first pixel opening,
wherein the first color filter has a structure extending from the first pixel opening in a plan view, and
wherein the first color filter has a rhombus shape in a plan view.

17. The organic light emitting display apparatus of claim 16, further comprising:
a second semiconductor element disposed on the substrate;
a third electrode electrically connected to the second semiconductor element;
a second pixel defining layer disposed on the third electrode, wherein a second pixel opening, which exposes a portion of the third electrode, is defined through the second pixel defining layer;
a second organic light emitting layer disposed on the exposed portion of the third electrode through the second pixel opening;
a fourth electrode disposed on the second organic light emitting layer and the second pixel defining layer; and
a second color filter disposed over the second pixel opening,
wherein the second color filter has a structure extending from the second pixel opening in a plan view,
wherein the second color filter has a rhombus shape in a plan view, and
wherein an area of the first pixel opening is greater than an area of the second pixel opening in a plan view.

18. The organic light emitting display apparatus of claim 17, wherein the first and second color filters contact each other in a plan view.

19. The organic light emitting display apparatus of claim 18, wherein a side of the rhombus shape of the first color filter and a side of the rhombus shape of the second color filters contact each other in a plan view.

20. The organic light emitting display apparatus of claim 17, wherein
the first color filter is a red color filter or a blue color filter, and
the second color filter is a green color filter.
